(19) United States
(12) Patent Application Publication
(10) Pub. No.: US 2014/0015119 A1
(43) Pub. Date: Jan. 16, 2014

(54) SEMICONDUCTOR DEVICE/ELECTRONIC COMPONENT MOUNTING STRUCTURE

(71) Applicant: Manabu Bonkohara, Kangawa (JP)

(72) Inventor: Manabu Bonkohara, Kangawa (JP)

(73) Assignee: ZYCUBE CO., LTD., Kanagawa (JP)

(21) Appl. No.: 13/976,813

(22) PCT Filed: Dec. 27, 2011
(86) PCT No.: PCT/JP2011/080281

§ 371 Date: Sep. 16, 2013

(30) Foreign Application Priority Data
Dec. 27, 2010 (JP) 2010-290003

(51) Int. Cl. H01L 23/46

(52) U.S. Cl. CPC H01L 23/46
USPC 257/713

(57) ABSTRACT

To provide a mounting structure of a semiconductor device/electronic component that suppresses temperature rise of a semiconductor device and/or an electronic component having large power consumption due to heat generation thereof, resulting in stable operation.

The mounting comprises an interposer 10; a semiconductor device 11 mounted on the surface 10a of the interposer 10; and a cover 12 that forms an inner space S along with the interposer 10; wherein the cover 12 is closely adhered and fixed on the surface 10a of the interposer 10 to so as to include the semiconductor device 11. The cover 12 has an inlet 13 for introducing a heat-absorbing fluid L from outside, and an outlet 14 for discharging the fluid L from the inner space S to outside. The inner space S is a closed space excluding the inlet 13 and the outlet 14.

### TECHNICAL FIELD

The present invention relates to a mounting structure of a semiconductor device/electronic component, and more particularly, to a mounting structure of a semiconductor device/electronic component using an interposer, which is possible to suppress the rise in the operating temperature of a semiconductor device and/or an electronic component whose power consumption is large, thereby stabilizing the operation of the semiconductor device and/or the electronic component.

### BACKGROUND ART

In recent years, technological advances in the semiconductor industries typified by silicon are large, regardless of industrial and consumer applications, contributing significantly to size reduction, weight reduction, cost lowering, and performance advancement of equipment and systems. On the other hand, the request to improving semiconductor devices is not stopped and as a result, higher integration, higher speed, and more sophistication as well as miniaturization are expected. As a measure to meet these requirements, the dimensions of unit elements (e.g., transistors) that constitute a semiconductor device are sometimes miniaturized, thereby increasing the total number of the unit elements to be mounted. The advantage of this measure is increase in operating speed (higher speed) due to miniaturization and increase in function (or, total number reduction of semiconductor devices required) due to high integration. However, higher speed and/or higher integration increase power consumption in the interior of a semiconductor device. As a result, the risk of operation destabilization or damage of a semiconductor device itself becomes large. To reduce this risk, heat dissipation technology (or, cooling techniques) of a semiconductor device is essential.

Many techniques for lowering the operating temperature of a semiconductor device have been developed so far. For example, there is known a technique for cooling a semiconductor device where radiating fins (which are often made of aluminum alloy) are attached to a high-power semiconductor device and air flows are blown to the fins. When the power consumption is comparatively low (e.g., a few watts), this technique is resolvable. However, with the latest semiconductor devices, power consumption has become even greater and thus, the power consumption may reach 100 watts or more in a CPU of a computer or the like. For this reason, with such the high power consuming semiconductor device as described here, if heat dissipation is not sufficient, the temperature of the semiconductor device rises and as a result, thermal runaway or thermal damage may occur. Therefore, it may be said that the upper limit of operation of the semiconductor device is dominated by the heat dissipation technology.

With a “stacked module” formed by stacking a plurality of semiconductor devices, there is an advantage that higher integration can be realized comparatively easily. In such the configuration, power consumption of a semiconductor device positioned in a lower layer increases not only the temperature of this semiconductor device but also the temperature of a semiconductor device located in an upper layer with respect to this semiconductor device. Therefore, when a semiconductor device with a sensitive characteristic to its operating temperature is arranged in an upper layer of the stacked module, there is a possibility that the operation of the entire stacked module becomes unstable. For this reason, in the case of the stacked module, it is preferred that a mounting structure that no heat transfer occurs between the stacked semiconductor devices by discharging the heat generated from a semiconductor device whose power consumption is large to the outside of the stacked module before this heat is transferred to a semiconductor device located in an upper layer.

As a cooling technique of stacked semiconductor devices (a stacked module), conventionally, the mounting structure shown in FIG. 7 has ever been proposed. This figure is published in Patent Document 1 as FIG. 1A.

In FIG. 7, the chip stack 110 is formed by the stack of three semiconductor chips denoted by the reference numerals 110a, 110b, and 110c. Each of the chips 110a, 110b, and 110c comprises channels 175 formed by etching. (In FIG. 7, the reference numeral 175 denotes the typical channels.) The chip stack 110 is designed to be cooled by flowing a fluid (coolant) into the channels 175. This fluid flows in the narrow channels 175 which are formed among the stacked chips 110a, 110b, and 110c. In addition, in the case where the chips 110a, 110b, and 110c are formed by a semiconductor substrate, the thicknesses of the channels 175 are usually several hundreds micrometers or less.

The semiconductor chips 110a, 110b, and 110c are vertically interconnected with TSVs (Through Silicon Vias) indicated by the reference numeral 123.

### PRIOR ART

### Patent Document

Patent Document 1: U.S. Patent Application Publication No. 2009/031186

### SUMMARY OF THE INVENTION

### Problems to be Resolved by the Invention

With the conventional mounting structure of a semiconductor device shown in FIG. 7, the channels 175 are formed like a “corridor including many bristling pillars”, and the height of the channels 175 is several hundreds micrometers or less. Thus, it seems that a high pressure is needed to flow the fluid (refrigerant) into channel 175.

Furthermore, the flowing direction of the fluid is indicated by rightward arrows and downward arrows illustrated at a position below the reference numeral 111 in FIG. 7. The fluid introduced around the chip stack 110 along the downward arrows not only flows into the channels 175 among the chips 110a, 110b, and 110c along the rightward arrows but also flows around the chips 110a, 110b, and 110c. Taking the fact that the height of the channels 175 is low and a wide space exists around the chips 110a, 110b, and 110c into consideration, it is difficult to pour the fluid into only the channels 175, and a large part of the fluid flows along the periphery of the chips 110a, 110b, and 110c. Moreover, since the shape (the shape along the flowing direction of the fluid) of the channels 175 of the chips 110a, 110b, and 110c are different from each other, it is difficult to realize a uniform flow of the fluid in all the channels 175 formed in the respective chips 110a, 110b, and 110c.

For this reason, with the conventional mounting structure shown in FIG. 7, it is not always easy to realize sufficient cooling (or, radiation from the chips 110a, 110b, and 110c).

Further, since the power consumption of the chip 110c disposed in a lowest layer of the chip stack 110 will cause not only the temperature rise of the chip 110c itself but also the temperature rise of the chips 110a and 110b disposed in upper layers than the chip 110c, it is preferred that the chip stack 110 itself can be cooled and that the heat from the chip 110c in the low layer is less likely to be transferred to the chips 110a and 110b in the upper layers. However, the formation of a uniform flow of the fluid in the channels 175 is difficult to achieve. Thus, it is difficult to suppress the heat conduction among the chips 110a, 110b, and 110c.

The present invention was created taking the aforementioned circumstances into consideration, and an object of the present invention is to provide a mounting structure of a semiconductor device/electronic component that suppresses temperature rise of a semiconductor device and/or an electronic component due to its heat generation to result in stable operation even if the semiconductor device and/or the electronic component has large power consumption.

Another object of the present invention is to provide a mounting structure of a semiconductor device/electronic component that suppresses temperature rise of a stacked module formed by stacking semiconductor devices by suppressing heat conduction among the semiconductor devices.

Other objects of the present invention not specified herein will become apparent from the following description and the accompanying drawings.

### Means for Solving the Problems

(1) A mounting structure of a semiconductor device/electronic component according to the present invention comprises:

an interposer;

one or more semiconductor devices or one or more electronic components mounted on a surface of the interposer; and

a cover that forms an inner space along with the interposer, wherein the cover is closely adhered and fixed on the surface of the interposer to so as to include the one or more semiconductor devices or the one or more electronic components;

wherein the cover has an inlet for introducing a heat-absorbing fluid from outside, and an outlet for discharging the fluid from the inner space to outside; and

the inner space is a closed space excluding the inlet and the outlet.

With the mounting structure of a semiconductor device according to the present invention, the aforementioned structure is provided and thus, when the heat-absorbing fluid is introduced into the inner space from the outside by way of the inlet of the cover with an arbitrary fluid supplying means, the fluid flows around the semiconductor device or the electronic component located in the inner space, and is discharged to the outside through the outlet of the cover. Unlike the conventional mounting structure of a semiconductor device shown in FIG. 7, the inner space is a closed one except for the inlet and the outlet; therefore, the fluid which has been introduced into the inner space flows evenly around the semiconductor device or the electronic component and absorbs effectively the heat generated from the semiconductor device or the electronic component and then, the fluid is discharged to the outside. That is, in addition to the heat dissipation effect to the outside by way of the cover and the interposer, the heat dissipation by the fluid can be utilized effectively.

Accordingly, even if the semiconductor device or the electronic component has large power consumption, it is possible to operate the semiconductor device or the electronic component stably by suppressing the temperature rise due to the heat generation of the semiconductor device or the electronic component.

Furthermore, when the semiconductor device or the electronic component is a stacked module formed by stacking two or more semiconductor devices, the fluid can be flowed not only in the gap between the stacked module and the interposer and the gap between the stacked module and the cover but also in the gap(s) among the semiconductor devices located in the stacked module by introducing the fluid into the inner space from the outside by way of the inlet of the cover. Accordingly, the heat conduction among the semiconductor devices in the stacked module can be suppressed.

For this reason, when the semiconductor device or the electronic component is a stacked module formed by stacking two or more semiconductor devices, the heat conduction among the semiconductor devices in the stacked module can be suppressed and as a result, the temperature rise of the stacked module can be suppressed.

(2) In a preferred embodiment of the mounting structure of a semiconductor device/electronic component according to the present invention, means for pressurizing and introducing the fluid into the inner space (e.g. pump) is further provided.
(3) In another preferred embodiment of the mounting structure of a semiconductor device/electronic component according to the present invention, the cover has a fixing leg and the interposer has a fixing leg receiving portion; and

the cover is fixed to the interposer by closely contacting the fixing leg of the cover with the fixing leg receiving portion of the interposer.

(4) In still another preferred embodiment of the mounting structure of a semiconductor device/electronic component according to the present invention, the cover is formed by a frame and a lid. In this embodiment, there is an advantage that the frame and the lid can be made of different materials according to the necessity,
(5) In this specification, related words are defined as follows:

Semiconductor device: This indicates any semiconductor device, including the following (i) and a (ii).

(i) A semiconductor chip (bare chip) which is cut out from a semiconductor wafer after the wafer process is completed. This semiconductor chip includes a so-called integrated circuit chip on which at least one semiconductor element such as a transistor and a diode is arranged.
(ii) The aforementioned semiconductor chip with a package. This packaged semiconductor chip includes a variety of packaged one, such as a ball grid array (BGA), a chip-size package (CSP), or the like.

Stacked module: This indicates any structure in which two or more semiconductor devices are stacked. (Various interconnection methods among the respective layers constituting the stacked structure, such as wire bonding, Through Silicon Vias (TSVs), or the like are known; however the interconnection method is not limited.)

Electronic component: This indicates any component that is also referred to as a passive element, such as a resister, a capacitor (condenser), and an inductor (coil). This may have a structure (e.g., a module resister) including a plurality of single elements (individual parts). Moreover, a sensor and an actuator having a specific function is included in the electronic component. Further, the actuator and the sensor in which a signal processing circuit and/or a driving circuit is/are integrated are also included in the electronic component.

Interposer: This indicates a “substrate” on which the semiconductor device, the stacked module, or the electronic component is/are mounted. On the surface of the interposer, electrical connection points, which are to be connected to the electrical connection points (which are also referred pads) provided on the semiconductor device, the stacked module, or the electronic component, are formed. Further, on the back of the interposer, electrical contacts (for example, conductive balls arranged in a grid array), which are to be electrically connected to a printed circuit board or the like is formed. Conductive paths are formed among the electrical connection points and the electrical contacts formed respectively on the surface and back of the interposer in many cases. Wiring patterns called “rewiring layers” are respectively provided on the surface and back of the interposer in many cases. Note that a “circuit board” may be inserted between the semiconductor devices that constitute the stacking module “to form electrically conductive paths between the semiconductor devices disposed above and below”. This “circuit board” may be termed an “interposer”. However, in this specification, this “circuit board” is not included in the “interposer”.

Fluid: This indicates a gas or a liquid, which has a heat dissipating or heat exhausting effect by absorbing heat due to heat conduction. A fluid with such the function is also referred to as “refrigerant”. Concrete examples are (i) fluorocarbons, non-CFC, etc. (which are frequently used and which have many types), (ii) an organic compound, such as butane and iso-butane, and (iii) an inorganic compound, such as hydrogen, helium, ammonia, water, and carbon dioxide.

The shape of the cover depends on the external shape of the semiconductor device or the electronic component; it is preferred that the shape of the cover is of a rectangular parallelepiped (including a cube). The vertices and edges (a line segment formed by intersecting planes) of a rectangular parallelepiped may be smooth. The positions of the inlet and the outlet formed on the cover have many alternatives. For example, (a) the inlet and the outlet are positioned on “opposing faces”, respectively; (b) the inlet and the outlet are positioned on the “opposing faces” and the respective “horizontal positions” are vertically deviated from each other; (c) the inlet and the outlet are positioned on the “top surface”; and (d) the inlet and the outlet are positioned on the “top surface” and the inlet and the outlet are respectively arranged adjacent to the opposing corners of the “top surface” (the vertexes of the cover). The positions of the inlet and the outlet are determined in such a way that the flow of the fluid is smooth and that the heat generated in the semiconductor device or the electronic component can be efficiently absorbed.

A member made of a good heat conductor may be inserted between the cover and the semiconductor device (the uppermost semiconductor device in the case of the stacked module formed by stacking a plurality of semiconductor chips). Since the good heat conductor is used, the heat generated in the semiconductor device is dissipated to the outside of the cover not only by the fluid but also through the path formed by the semiconductor device,→the good heat conductor,→the upper part of the cover,→and the upper space of the cover, which is advantageous. Moreover, if the elastic modulus of the member of the good heat conductor is enlarged, for example, if the member is made of a soft (elastic) resin material whose thermal conductivity is large, the member acts as a cushion. Thus, when the cover is close contacted with the surface of the interposer, the semiconductor device is pressed against the interposer, as a result, the electrical connection characteristic between the interposer and the semiconductor device can be improved.

As the material of the cover, a metal, a resin or the like can be used. If an increase in the cooling (radiation) effect is desired, it is preferred to form the cover by a metallic material; however, the present invention is not limited to this. If the cover is made of a resin material, a metal layer may be provided on the surface or back of the cover or the surface and back of the cover in order to increase the heat cooling (heat dissipation) effect.

The cover may be formed as a unitary structure and then, the cover may be directly fixed in close contact to the surface of the interposer. In order to fix the cover in close contact with the surface of the interposer, an adhesive (it is preferred for the adhesive that a gas generated in the solidification process does not adversely affect the characteristics of the semiconductor device or the electronic component) may be used. Further, when the cover is made of a metallic material, a metal-to-metal bonding (e.g., welding, soldering or the like) may be applied between the metal layer provided on the surface of the interposer and the cover.

The cover may be formed by multiple structural components, and these components may be incorporated (assembled) to result in the cover. For example, a “lid” (which is like a flat plate) on which the inlet and the outlet are disposed and a “frame” that forms the side parts of the cover are combined together to form the cover. In this configuration example, the bottom face of the frame is brought into close contact with the surface of the interposer and the top face of the frame is brought into close contact with the bottom face of the lid. The material of the frame is not necessarily the same as the material of the cover. For example, there is a combination that the lid is made of a metal material and the frame is made of a resin or glass.

An adhesive (it is preferred for the adhesive that a gas generated in the solidification process does not adversely affect the characteristics of the semiconductor device or the electronic component) may be used for close bonding between the lid and the frame and for close fixing between the frame and the interposer. If the lid and the frame are made of metal materials, a metal-to-metal bonding (e.g., welding or soldering) may be used. When the lid is made of a metal (e.g., aluminum) and the frame is made of a glass, electrostatic bonding (bonding method of glass and metal) may be used. If the frame is made of a metallic material, a metal-to-metal bonding (e.g., welding or soldering) may be used for the bonding between the metal layer provided on the surface of the interposer and the frame. When the frame is made of a glass and the surface of the interposer is made of a metal (or, the combination or vice versa), an electrostatic bonding may be used.

### Advantageous Effects of the Invention

With the mounting structure of a semiconductor device/electronic component according to the present invention, even when a semiconductor device or an electronic component having large power consumption is mounted, the temperature rise of the semiconductor device or the electronic component due to its heat generation it can be suppressed to result in stable operation. Furthermore, in the case of a stacked module formed by stacking two or more semiconductor devices, thermal conduction among the semiconductor devices can be suppressed to result in the temperature rise suppression of the stacked module.

### BRIEF DESCRIPTION OF THE DRAWINGS

FIG. 1 is an explanatory cross-sectional view showing a mounting structure of a semiconductor device/electronic component according to a first embodiment of the present invention.

FIG. 2 is an explanatory cross-sectional view taken along the line A-A in FIG. 3, showing a mounting structure of a semiconductor device/electronic component according to a second embodiment of the present invention.

FIG. 3 is a perspective view showing the state where the cover is separated from the interposer in the mounting structure of a semiconductor device/electronic component according to the second embodiment of the present invention.

FIG. 4 is an explanatory cross-sectional view taken along the line B-B in FIG. 5, showing a mounting structure of a semiconductor device/electronic component according to a third embodiment of the present invention.

FIG. 5 is a perspective view showing the state where the cover, the frame and the interposer are separated from each other in the mounting structure of a semiconductor device/electronic component according to the third embodiment of the present invention.

FIG. 6 is an explanatory view showing a mounting structure of a semiconductor device/electronic component according to a fourth embodiment of the present invention.

FIG. 7 is a cross-sectional view showing the conventional mounting structure of a semiconductor device.

### MODE FOR CARRYING OUT THE INVENTION

Hereinafter, preferred embodiments of a mounting structure of a semiconductor device/electronic component of the present invention will be described with reference to the accompanying drawings.

### First Embodiment

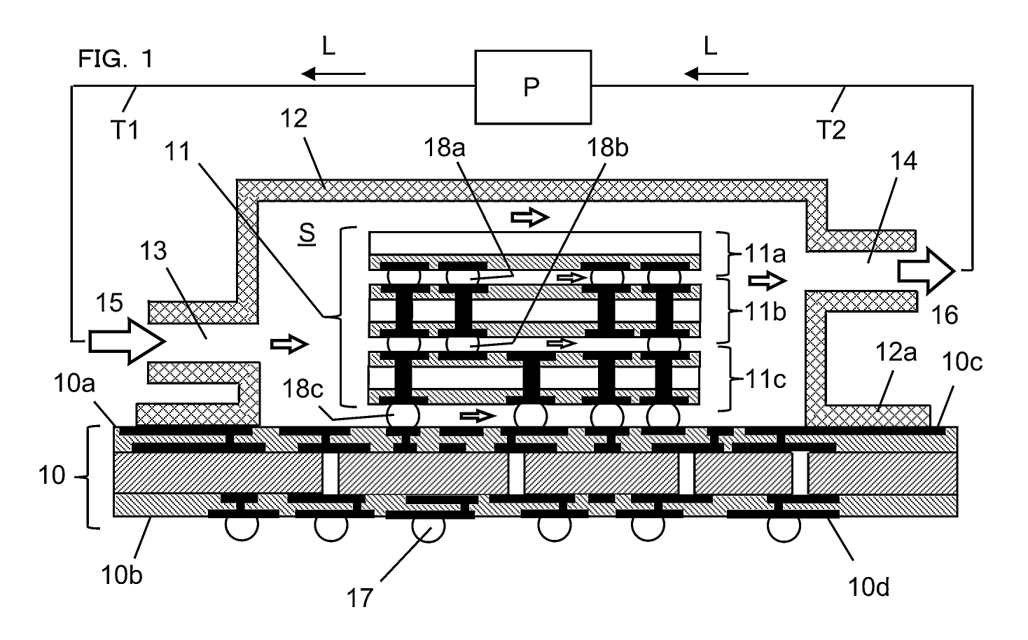

A mounting structure of a semiconductor device/electronic component according to a first embodiment of the present invention is shown in FIG. 1.

In FIG. 1, 10 denotes an interposer, 11 denotes a semiconductor device mounted on the surface 10a of the interposer 10, and 12 is a cover fixed in close contact with the surface 10a of the interposer 10.

The cover 12 has a shape including (wrapping) the semiconductor device 11; here, the cover 12 has a box shape of an approximately rectangular parallelepiped whose lower surface is opened. The cover 12 and the interposer 10 constitute an inner space S of an approximately rectangular parallelepiped, and the semiconductor device 11 is located in the inner space S. The cover 12 has an inlet 13 for introducing a heat-absorbing fluid L into the inner space S from the outside and an outlet 14 for discharging the fluid L from the inner space S to the outside. The inner space S is a closed space with the exception of the outlet 14 and inlet 13.

An arrow 15 indicates the flow of the fluid L flowing into the inlet 13 from the outside. An arrow 16 indicates the flow of the fluid L to flow to the outside from the outlet 14. The fluid L flows into the inlet 13 as shown by the arrow 15 and enters the inner space S. After flowing through the inner space S, the fluid L flows out from the outlet 14 as shown by the arrow 16.

One end of a tube T1 and one end of a tube T2, which are made of plastic or metal, are connected to the inlet 13 and the outlet 14, respectively. The other end of the tube T1 and the other end of the tube T2 are respectively connected to the delivery port and the return port of a pump P that applies a predetermined pressure to the fluid L and that supplied the fluid L thus pressurized to the inlet 13. As the pressurizing mechanism of the fluid L, any one that applies a predetermined pressure to the fluid L and that supplied the fluid L thus pressurized to the inlet 13 is applicable. Any one other than the pump can also be used for this purpose.

The heat-absorbing fluid L is fed into the inner space S of the cover 12 to have a predetermined pressure with the pump P via a tube T1. The fluid 1 thus fed is returned to the pump P via a tube T2. In this way, the fluid L is circulated from the pump P,→the tube T1,→the inner space S,→the tube T2, and→the pump P. The fluid L absorbs the heat generated from the semiconductor device 11 in the inner space S, and naturally dissipates the heat thus absorbed while flowing in the outside. In this way, the heat generated from the semiconductor device 11 is allowed to dissipate to the outside of the cover 12. For this reason, the liquid L is cooled when it is fed to the inlet 13.

It is preferred that the fluid L has a property that absorbs the heat generated by the semiconductor device 11. Examples of such the fluid L are (1) Freon-CFC-free acids, (2) an organic compound such as butane, and iso-butane, and (3) an inorganic compound such as hydrogen, helium, ammonia, water, and carbon dioxide. These are all referred as “refrigerant”; however, in the present embodiment, the fluid L is not to be limited to the type of refrigerants.

In the first embodiment, in order to increase the cooling effect, the inlet 13 is disposed at a position relatively closer to the interposer 10 (a lower position in Figure), and the outlet 14 is disposed at a position relatively further from the interposer 10 (a higher position in Figure).

The interposer 10 may be formed of a printed circuit board, a semiconductor material, or the like. Wiring structures 10c and 10d, each of which is formed by a plurality of wiring layers, are respectively formed on the back surface 10a and the back 10b of the interposer 10. Conductive balls 17 (which constitute electrical contacts) for electrical connection to a printed circuit (not shown) or the like are provided on the outer surface of the wiring structure 10d which is placed on the back 10b of the interposer 10, wherein the balls 17 constitute a ball grid array. Conductive balls 18c (which constitute electrical contacts) for electrical connection of the semiconductor device 11 are provided on the outer surface of the wiring structure 10c which is placed on the surface 10a of the interposer 10, wherein the balls 18c also constitute a ball grid array.

In the first embodiment, the semiconductor device 11 is a stacked module comprising three chip-like semiconductor devices (semiconductor chips) stacked. This stacked module comprises a first semiconductor chip 11a located in the uppermost layer, a second semiconductor chip 11b located in the intermediate layer wherein penetrating electrodes are formed therein, and a third semiconductor chip 11c located in the lowermost layer wherein penetrating electrodes are formed therein.

The third semiconductor chip 11c in the lowermost layer is electrically connected to the wiring structure 10c placed on the surface 10a of the interposer 10 with the conductive balls 18c. A gap is formed between the third semiconductor chip 11c and the wiring structure 10c placed on the surface 10a of the interposer 10.

The second semiconductor chips 11b in the intermediate layer is electrically connected to the third semiconductor chip 11c in the lowermost layer with the conductive balls 18b. The balls 18b arranged between the second and third semiconductor chips 11b and 11c constitute a ball grid array. A gap is formed between the second and third semiconductor chips 11b and 11c also.

The first semiconductor chip 11a in the uppermost layer is electrically connected to the second semiconductor chip 11b in the intermediate layer with the conductive balls 18a. The balls 18a arranged between the first and second semiconductor chips 11a and 11b also constitute a ball grid array. A gap is formed between the first and second semiconductor chips 11a and 11b also.

In this way, the first to third semiconductor chips 11a, 11b, and 11c are interconnected with each other with the ball grid arrays; the third semiconductor chip 11c and the interposer 10 also are interconnected with the ball grid array; and the gaps are present in the respective interconnection regions thereof. Thus, the fluid L is able to flow through these gaps. However, these gaps, if necessary, may be filled with a material such as a resin (which is called under-filler). In this case, the fluid L cannot flow through these gaps.

The structure of the semiconductor device 11 shown in FIG. 1 is an example and therefore, the present invention is not limited to this structure. For example, the first to third semiconductor chips 11, 11b, 11c that constitute the semiconductor device 11 may be a stacked module which is electrically connected using bonding wires. Moreover, a single semiconductor chip (a semiconductor device) may be mounted on the surface 10a of the interposer 10 and two or more semiconductor chips (semiconductor devices) may be mounted on the surface 10a of the interposer 10. Furthermore, instead of the semiconductor device 11, one or more electronic components may be mounted on the surface 10a of the interposer 10.

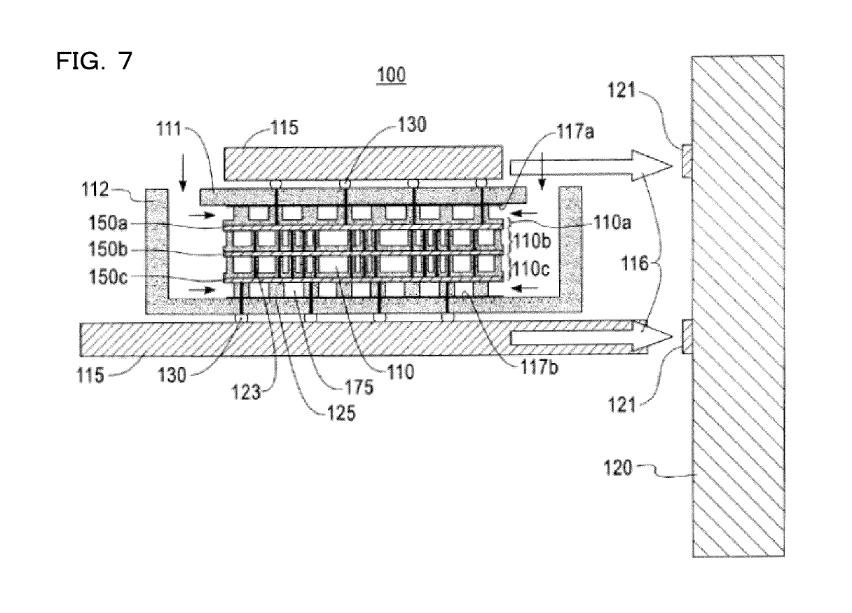

With the conventional mounting structure of the semiconductor device shown in FIG. 7, the fluid is designed to flow into the extremely narrow gap (for example, a space corresponding to the gap between the semiconductor chips 11a and 11b, wherein this space is often has a size of 100 micrometers or less); however, in the first embodiment, the fluid L is designed to flow into around the periphery of the stacked module as the semiconductor device 11; which are different from each other on these points. Since the fluid L is designed to flow into the wide inner space S provided in the cover 12 in the first embodiment, it is possible to easily realize a desired flow of the fluid L. The size of the inner space S is dependent on the sizes of the semiconductor device 11 and the cover 12; the size of the inner space S can be set at about several millimeters easily.

In the first embodiment, when an under-filler is plugged into among the first to third semiconductor chips 11a, 11b, and 11c, the fluid L never flows into the gap between the semiconductor chips 11a and 11b the gap between the semiconductor chips 11b and 11c. However, when an under-filler is not plugged into these gaps, some of the fluid L flows into these gaps. In this case, however, the amount of the fluid L flowing into these gaps is small and therefore, the fluid L merely serves as part of the heat dissipation effect.

Regarding the gap between the third semiconductor chip 11c and the interposer 10 also, similarly, if an under-filler is not plugged, a part of the fluid L flows into this gap, contributing to the heat dissipation effect

In order to make the heat absorption effective, it is possible to form the cover 12 with a metallic material and to insert a good thermal conductor into between the cover 12 and the semiconductor device 11 (more specifically, the first semiconductor chip 11a in the uppermost level). By inserting the good thermal conductor, the heat generated in the semiconductor device 11 is not only radiated by the fluid L to the outside of the cover 12 is but also dissipated through the path formed by the semiconductor device 11,→the good thermal conductor,→the upper part of the cover 12,→and the upper space of the cover 12. With this configuration, the fluid L does not flow into the gap between the first semiconductor chip 11a and the cover 12 due to the presence of the good thermal conductor, wherein the fluid L flows only along the side faces of the semiconductor device 11.

As the material of the good thermal conductor, a material having a large elastic modulus, for example, a soft (elastic) resin material having a large thermal conductivity can be chosen. In this case, this good thermal conductor the functions as a cushion and therefore, when the cover 12 is fixed in close contact to the surface 10a of the interposer 10, the electrical connection characteristics between the semiconductor device 11 and the interposer 10 can be improved.

As the material of the cover 12, a metal, a resin or the like can be used. When the cooling effect from the surface of the cover 12 is increased, it is preferable to use a metal material. For example, in the case where the cover 12 is formed by bending or drawing a thin metal plate, the edges of the cover 12 will be smooth without having any sharp edges. Although angular edges are illustrated in FIG. 1, the edges and vertices may be smooth. It is possible to form the metal-made cover 12 by using a mold casting technique, such as casting and lost wax casting. When making the cover 12 with resin, it is possible to increase the heat dissipation effect by depositing a metal layer on the surface and/or the back of the cover 12.

When the cover 12 is fixed in close contact to the surface 10a of the interposer 10, an adhesive can be used. When the cover 12 is made of a metal material and the wiring structure 10c on the surface 10a of the interposer 10 includes a metal layer, the metal-to-metal bonding techniques, such as soldering and welding, may be utilized.

With the mounting structure of a semiconductor device according to the first embodiment, as described above, the aforementioned structure is provided. Thus, when the heat-absorbing fluid L is introduced into the inner space S from the outside by way of the inlet 13 of the cover 12 with the pump P, the fluid L flows around the semiconductor device 11 located in the inner space S, and is discharged to the outside through the outlet 14 of the cover 12. Unlike the conventional mounting structure of a semiconductor device shown in FIG. 7, the inner space S is a closed one except for the inlet 13 and the outlet 14; therefore, the fluid L which has been introduced into the inner space S flows evenly around the semiconductor device 11 and absorbs effectively the heat generated from the semiconductor device 11 and then, the fluid L is discharged to the outside. That is, in addition to the heat dissipation effect to the outside by way of the cover 12 and the interposer 10, the heat dissipation by the fluid L can be utilized effectively.

Accordingly, even if the semiconductor device 11 has a large power consumption, it is possible to operate the semiconductor device 11 stably by suppressing the temperature rise due to the heat generation of the semiconductor device 11.

Further, since the semiconductor device 11 is the stacked module formed by stacking the three semiconductor chips 11a, 11b, and 11c, the fluid L can be flowed not only in the gap between the stacked module and the interposer 10 and the gap between the stacked module and the cover 12 but also in the gaps among the semiconductor chips 11a, 11b and 11c located in the stacked module by introducing the heat-absorbing fluid L into the inner space S from the outside by way of the inlet 13 of the cover 12. Accordingly, the heat conduction among the semiconductor chips 11a, 11b and 11c in the stacked module can be suppressed, thereby suppressing the temperature rise of the stacked module.

### Second Embodiment

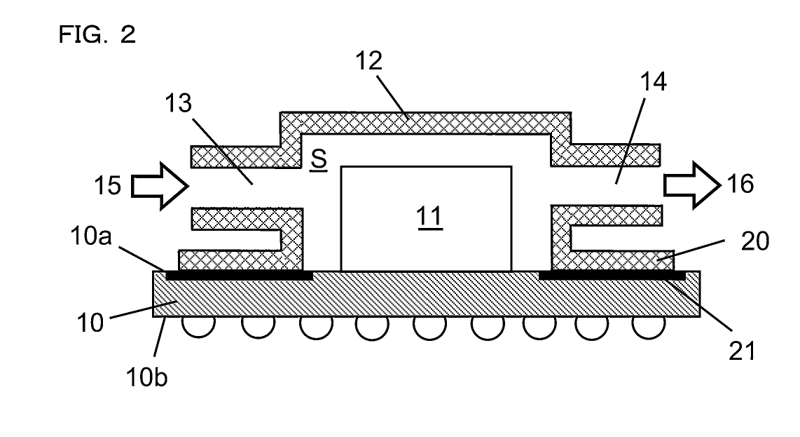

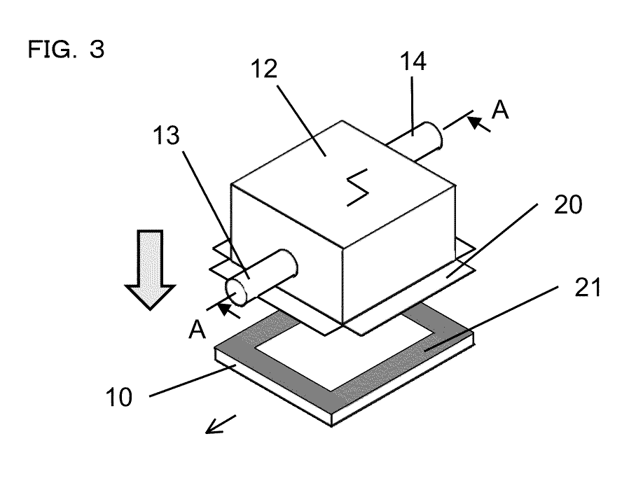

FIGS. 2 and 3 show a mounting structure of a semiconductor device/electronic component according to a second embodiment of the present invention. In both figures, the same reference numerals as those used in the mounting structure of a semiconductor device/electronic component according to the first embodiment shown in FIG. 1 denote the same structural elements.

Fixing legs 20 are provided on the bottom portion of the cover 12, and fixing leg receiving portions 21 for receiving the fixing legs 20 are provided on the surface 10a of the interposer 10. As shown by the thick arrow in FIG. 3, the cover 12 is fixed onto the surface 10a of the interposer 10 by bringing the fixing legs 20 of the cover 12 into close contact with the fixing leg receiving portions 21 of the interposer 10. Since the mounting structure of a semiconductor device/electronic component according to the second embodiment has the same configuration as the mounting structure of a semiconductor device/electronic component according to the aforementioned first embodiment except for this point, the explanation about it is omitted here.

Although the fixing legs 20 are included in the cover 12, the legs 20 are not necessarily formed to be integrated with the cover 12. The part of the cover 12 excluding the legs (which is called a cover body and which includes the inlet and the outlet 14), and the legs 20 may be formed separately and thereafter, the cover body and the legs 20 may be integrated with each other. Further, the cover body and the fixing legs 20 may be formed integrally from the beginning. Here, the legs 20 are composed of four rectangular members which are connected respectively to the four edges of the bottom portion (the lower surface of which is opened) of the cover body having a box-like shape of an approximately rectangular parallelepiped; the legs 20 have a shape similar to the brim of a hat as a whole. However, it is needless to say that the legs 20 may have any other configuration than this if the bottom portion of the cover 12 can be fixed in close contact to the surface 10a of the interposer 10.

The fixing leg receiving portions 21 may be formed at the positions corresponding to the fixing legs 20 formed on the surface 10a of the interposer 10. The fixing leg receiving portions 21 may be formed as a part of the wiring structure 10c which is formed on the surface 10a of the interposer 10, and the portions 21 may be formed separately from the wiring structure 10c.

Next, the connection between the fixing legs 20 and the fixing leg receiving portions 21 will be described. As the matters required for this connection, mechanical adhesion strength, sealing ability for preventing leak of the fluid L, characteristic maintenance at a high temperature atmosphere (maintenance of the adhesive strength and maintenance of the sealing ability in the case where a difference of the thermal expansion coefficients exists), and corrosion resistance against the fluid L are considered. As materials for the fixing legs 20 and the fixing leg receiving portions 21 that satisfy these requirements, there are many alternatives. Some examples will enumerate in the following.

(a) Fixing legs: metal; Fixing leg receiving portion: resin

This is the case where, for example, the interposer 10 is made of resin, and the fixing leg receiving portions 21 are provided in the regions on the surface 10a of the interposer 10 excluding the wiring structure 10c (i.e., the regions where the resin that forms the interposer 10 is exposed). In this case, an adhesive such as epoxy can be used for the connection between the fixing legs 20 and the fixing leg receiving portions 21. In general, an adhesive often generates a gas in its drying process; therefore, it is necessary to select the material of an adhesive to be used so that any corrosion due to this gas will not occur.

(b) Fixing leg: metal; Fixing leg receiving portion: insulator such as oxide film

This is the case where, for example, the interposer 10 is made of a semiconductor such as silicon, and the fixing leg receiving portions 21 are made of an insulating material such as an oxide film or the like which is exposed on the surface 10a of the interposer 10. In this case, the aforementioned adhesive described in (a) can be used for the connection between the fixing legs 20 and the fixing leg receiving portions 21.

(c) Fixing leg: resin; Fixing leg receiving portion: resin

In this case, the adhesive described in (a) can be used for the connection between the fixing legs 20 and the fixing leg receiving portions 21; however, affinity between the material of the fixing legs 20 and the material of the fixing leg receiving portions 21 needs to be taken into consideration. This is because it is known that the adhesion force is lowered with respect to a particular material depending on the type of the adhesive used. In addition, to enhance the adhesion force, a primer or the like may be used in combination with the adhesive.

(d) Fixing leg: metal; Fixing leg receiving portion: metal

This is the case where the wiring structure 10c formed on the surface 10a of the interposer 10 is used as the fixing leg receiving portions 21. In this case, the aforementioned adhesive described in (a) can be used; however metal-to-metal bonding may also be used. For example, soldering or welding may be used. Furthermore, in this case, a suitable metal-to-metal bonding technique can be used in accordance with the materials that constitute the fixing legs 20 and the fixing leg receiving portions 21.

(e) Fixing leg: metal; Fixing leg receiving portion: glass (or, Fixing leg: glass; Fixing leg receiving portion: metal)

In this case, not only the aforementioned adhesive described in (a) can be used but also an electrostatic bonding technique can be applied.

In FIG. 2, the position of the inlet 13 and the position of the outlet 14 are set at the same height from the surface 10a of the interposer 10; however, the present invention is not limited this. For example, like the first embodiment shown in FIG. 1, the inlet 13 may be located at a relatively lower position (a position closer to the interposer 10) and the outlet 14 may be located at a relatively higher position (a position further from the interposer 10).

As described above, with the mounting structure of a semiconductor device/electronic component according to the second embodiment of the present invention, the same advantages as those in the mounting structure of a semiconductor device/electronic component according to the first embodiment can be obtained and at the same time, an advantage that the close contacting and fixing of the cover 12 to the surface of the interposer 10 is easy can be obtained.

### Third Embodiment

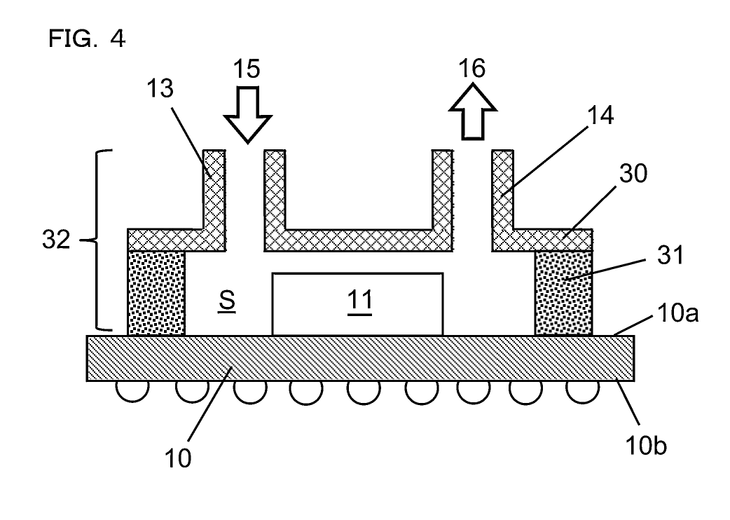

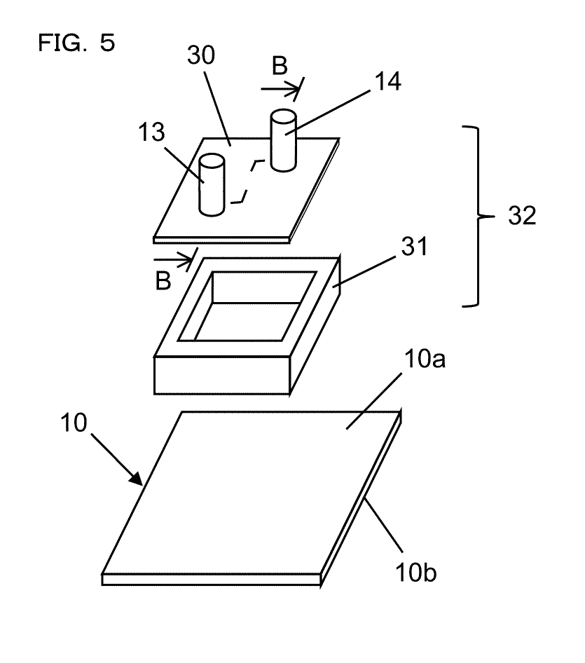

FIG. 4 and FIG. 5 show a mounting structure of a semiconductor device/electronic component according to a third embodiment of the present invention. In both figures, the same reference numerals as those used in the mounting structure of a semiconductor device/electronic component according to the first embodiment shown in FIG. 1 denote the same structural elements.

In the third embodiment, a cover 32 is composed of a rectangular frame 31 and a rectangular lid 30, and the inlet 13 and the outlet 14 are formed on the lid 30. The mounting structure of the third embodiment is different from the mounting structure of the aforementioned first embodiment at these points. The lid 30 is connected to the top portion of the frame 31 to be integrated with the frame 31. The cover 32 is fixed to the surface 10a of the interposer 10 by bringing the bottom portion of the frame 31 in close contact with the surface 10a of the interposer 10.

In this way, the third embodiment is different from the aforementioned first and second embodiments in that the cover 32 is not formed integrally, but the lid 30 and the frame 31 are formed separately and then, they are integrated with each other, thereby constituting the cover 32. The lid 30 and the frame 31 may be made the same material; but they are made of different materials as needed. Usually, the lid 30 is made of a material such as metal. The frame 31 is made of metal, resin, glass or the like.

The bottom portion of the frame 31 is fixed in close contact with the surface 10a of the interposer 10. The top portion of the frame 31 is bonded to the back of the lid 30. The inlet 13 and the outlet 14 are formed to protrude on the surface side of the lid 30.

Aforementioned many techniques can be applied for the bonding between the lid 30 and the frame 31 and the bonding between the frame 31 and the interposer 10 depending on the respective materials thereof. In a preferred embodiment, the cover 30 is formed by metal, the frame 31 is formed by glass, and the interposer 10 is formed by resin (i.e., a resin interposer) and then, the lid 30 and the frame 31 are integrated with each other by electrostatic bonding, resulting in the cover 32; the cover 32 (i.e. the frame 31) is brought into close contact and fixed to the surface 10a of the interposer 10 using an adhesive or the like.

The inlet 13 and the outlet 14 which are formed on the lid 30 are arranged upright along the vertical direction so that the fluid L flows up and down. In this configuration, a tube T1 and a tube T2 (which are usually made of resin or metal), which are respectively connected to the inlet 13 and the outlet 14, are disposed vertically with respect to the interposer 10. In general, many semiconductor devices and electronic components are mounted in a high density on a printed circuit board (not shown) on which the interposer 10 is to be placed; therefore, it may be preferred that the tubes T1 and T2 are arranged perpendicular to the printed circuit board. This configuration is prepared by taking the possibility of this case into account.

As described above, with the mounting structure of a semiconductor device/electronic component according to the third embodiment of the present invention, the same advantages as those in the mounting structure of a semiconductor device/electronic component according to the first embodiment can be obtained and at the same time, an advantage that the close contacting and fixing of the cover 32 to the surface of the interposer 10 is easy and that this configuration is available even if semiconductor devices or the like are implemented at a high density on a printed circuit board on which the interposer 10 is to be disposed can be obtained.

### Forth Embodiment

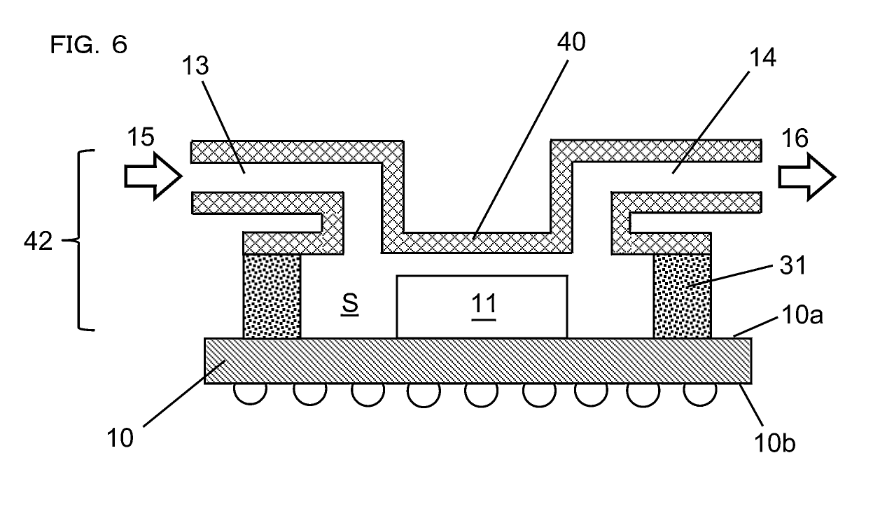

FIG. 6 shows a mounting structure of a semiconductor device/electronic component according to a fourth embodiment of the present invention. In this figure, the same reference numerals as those used in the mounting structure of a semiconductor device/electronic component according to the third embodiment shown in FIGS. 4 and 5 denote the same structural elements.

In the fourth embodiment, as shown in FIG. 6, a cover 42 is formed by a lid 40 having the inlet 13 and the outlet 14, and the frame 31 used in the third embodiment. The lid 40 is integrally connected to the top portion of the frame 31. The cover 42 is fixed to the surface 10a of the interposer 10 by bringing the bottom portion of the frame 31 in close contact with the surface 10a of the interposer 10.

In the fourth embodiment, unlike the aforementioned third embodiment, the inlet 13 and the outlet 14 are attached to the lid 40 so as to extend transversely. That is, the fluid L is designed to flow in the horizontal direction along the surface 10a of the interposer 10. In this configuration, the tubes T1 and T2, which are respectively connected to the inlet 13 and the outlet 14, are arranged parallel to the surface 10a of the interposer 10 and therefore, a mounting space can be ensured in the direction perpendicular to the interposer 10. Fore this reason, it is easy to increase the mounting density along the direction perpendicular to the interposer 10.

As described above, with the mounting structure of a semiconductor device/electronic component according to the fourth embodiment of the present invention, the same advantages as those in the mounting structure of a semiconductor device/electronic component according to the first embodiment can be obtained and at the same time, an advantage that the close contacting and fixing of the cover 42 to the surface of the interposer 10 is easy and that the mounting density along the direction perpendicular to the interposer 10 is easily increased can be obtained.

### (Modification)

The mounting (extension) directions of the inlet 13 and the outlet 14 shown in FIGS. 4 and 6 are examples, and the present invention is not limited these examples. For example, a combination that the inlet 13 is along the horizontal direction and the outlet 14 is along the vertical direction may be used. Furthermore, the inlet 13 or the outlet 14, or both of the inlet 13 and the outlet 14 may be mounted in an oblique direction or directions.

Further, the mounting (extension) directions of the inlet 13 and the outlet 14 in a horizontal plane may be set arbitrarily. That is, it is preferred that the mounting (extension) directions of the inlet 13 and the outlet 14 are determined according to which position the interposer 10 is disposed in such a way that the routing of the tubes T1 and T2 is easy on a printed circuit board (refer to the aforementioned third embodiment) on which the interposer 10 including the semiconductor device 11 is to be disposed.

### INDUSTRIAL APPLICABILITY

The mounting structure of a semiconductor device/electronic component according to the present invention may be utilized not only in the mounting field for facilitating heat dissipation but also in the field for shielding a semiconductor device or devices. For example, the present invention is applicable to a case where light from the outside is mixed as a noise into a signal transmission system using light, preventing the normal transmission operation. In such the case, the mounting structure of a semiconductor device/electronic component according to the present invention is effective in both of heat dissipation and light blocking.

### DESCRIPTION OF REFERENCE NUMERALS

10 interposer
10a surface of interposer
10b back of interposer
10c wiring structure on surface of interposer
10d wiring structure on back of interposer
12 cover
11 semiconductor device
11a semiconductor chip (chip-like semiconductor device)
11b semiconductor chip (chip-like semiconductor device)
11c semiconductor chip (chip-like semiconductor device)
12 cover
13 inlet
14 outlet
15 arrow
16 arrow
17 conductive ball
18a conductive ball
18b conductive ball
18c conductive ball
20 fixing leg
21 fixing leg receiving portion
30 lid
31 frame
32 cover
40 lid
42 cover
L fluid
P pump
S inner space
T1 tube
T2 tube

1. A mounting structure of a semiconductor device/electronic component comprising:
an interposer;
one or more semiconductor devices or one or more electronic components mounted on a surface of the interposer; and
a cover that forms an inner space along with the interposer, wherein the cover is closely adhered and fixed on the surface of the interposer to so as to include the one or more semiconductor devices or the one or more electronic components;
wherein the cover has an inlet for introducing a heat-absorbing fluid from outside, and an outlet for discharging the fluid from the inner space to outside; and
the inner space is a closed space excluding the inlet and the outlet.

2. The mounting structure of a semiconductor device/electronic component according to claim 1, further comprising means for pressurizing and introducing the fluid into the inner space.

3. The mounting structure of a semiconductor device/electronic component according to claim 1, wherein the cover has a fixing leg and the interposer has a fixing leg receiving portion; and
the cover is fixed to the interposer by closely contacting the fixing leg of the cover with the fixing leg receiving portion of the interposer.

4. The mounting structure of a semiconductor device/electronic component according to claim 1, wherein the cover is formed by a frame closely fixed on the surface of the interposer and a lid joined to the frame; and
the inlet and the outlet are provided on the lid.

5. The mounting structure of a semiconductor device/electronic component according to claim 2, wherein the cover has a fixing leg and the interposer has a fixing leg receiving portion; and
the cover is fixed to the interposer by closely contacting the fixing leg of the cover with the fixing leg receiving portion of the interposer.

6. The mounting structure of a semiconductor device/electronic component according to claim 2, wherein the cover is formed by a frame closely fixed on the surface of the interposer and a lid joined to the frame; and
the inlet and the outlet are provided on the lid.
